(19) United States
(12) Patent Application Publication
(10) Pub. No.: US 2025/0111813 A1
(43) Pub. Date: Apr. 3, 2025

(54) DIGITAL-TO-ANALOG CONVERSION DEVICE, DISPLAY DRIVER, AND DISPLAY DEVICE

(71) Applicant: LAPIS Technology Co., Ltd., Yokohama (JP)

(72) Inventor: Daisei NAGATA, Yokohama (JP)

(73) Assignee: LAPIS Technology Co., Ltd., Yokohama (JP)

(21) Appl. No.: 18/896,795

(22) Filed: Sep. 25, 2024

(30) Foreign Application Priority Data
Sep. 29, 2023 (JP) 2023-170545

(51) Int. Cl. G09G 3/20; H03M 1/68; H03M 7/16

(52) U.S. Cl. CPC G09G 3/2007; H03M 1/68; H03M 7/16; G09G 2310/027; G09G 2310/0286; G09G 2310/0291; G09G 2320/02

(57) ABSTRACT

A digital-to-analog conversion device includes a Gray code conversion circuit receiving a series of digital data pieces including binary codes, and generating Gray code data pieces obtained by respectively converting the digital data pieces into Gray codes; a decoder receiving the Gray code data pieces and a plurality of reference voltages having different voltage values, selecting two reference voltages including an overlap from the plurality of reference voltages based on the Gray code data pieces, and outputting the two reference voltages as a first selection voltage and a second selection voltage, respectively; and an amplifier circuit including first and second input terminals that respectively receive the first selection voltage and the second selection voltage, and generating an output voltage by amplifying a voltage obtained by interpolating the first selection voltage and the second selection voltage by a weighting ratio assigned to the first and second input terminals.

### CROSS-REFERENCE TO RELATED APPLICATION

This application claims the priority benefits of Japanese application no. 2023-170545, filed on Sep. 29, 2023. The entirety of the above-mentioned patent application is hereby incorporated by reference herein and made a part of this specification.

### BACKGROUND

### Technical Field

The disclosure relates to a digital-to-analog conversion device, a display driver for driving a display panel, and a display device.

### Description of Related Art

A known liquid crystal display device includes a display panel in which a plurality of data lines and a plurality of scan lines are arranged to intersect each other and in which display cells serving as pixels are formed at the intersections, as well as a source driver and a gate driver that drive the display panel (see, for example, Japanese Patent Application Laid-Open No. 2009-145492).

The source driver includes a shift register, a level shifter, a data register latch, a DA (digital-to-analog) conversion part, and an output amplifier part.

The shift register generates a plurality of latch timing signals for selecting latches in synchronization with a clock signal, and supplies the same to the data register latch.

The data register latch takes in, for example, n 8-bit display data pieces corresponding to each display cell based on a video signal, on the basis of each of the latch timing signals supplied from the shift register. The level shifter performs a level shift process on each of the n display data pieces to increase the amplitude of the signal level corresponding to each bit, and supplies each of the resulting level-shifted n display data pieces to the DA conversion part.

The DA conversion part includes a gamma circuit and n selection circuits (decoders) provided corresponding to the n display data pieces, respectively. The gamma circuit generates, for example, 256 voltages having different voltage values as reference voltages, and supplies the same to each of the n selection circuits. Each of the selection circuits selects, from the 256 reference voltages, a reference voltage that corresponds to the value indicated by the 8-bit display data piece which the selection circuit receives. With this configuration, the DA conversion part supplies the n reference voltages selected by the n selection circuits described above as n gradation voltages to the output amplifier part. The output amplifier part amplifies each of the n gradation voltages individually, and supplies the amplified voltages as output voltages to the n data lines of the display panel.

With the trend toward larger screen size and higher resolution for display panels in recent years, the period (one data period) in which the output voltage (gradation voltage) corresponding to one display data piece is charged to the display cell of the display panel has become shorter, and the output voltage is required to have a high-quality waveform in order to obtain the desired display quality.

However, the display data piece uses binary code. Even if the amount of change in luminance level of the display data piece supplied to the DA conversion part per horizontal scan period is slight, the number of changes in the logic level of each bit of the display data piece may be large.

For example, in the case where a display data piece changes the state from representing a luminance level of “126” to “127”, the 8-bit binary code changes from [01111110] to [01111111]. In other words, for a change in luminance level of “1”, the number of bits changed in the binary code is “1”.

However, in the case where the display data piece changes the state from representing a luminance level of “127” to “128”, the 8-bit binary code changes from [01111111] to [10000000].

Thus, in binary code, the Hamming distance between adjacent codes changes between “1” and the total number of bits (for example, 8). Therefore, in this case, even though the amount of change in luminance level is “1”, the Hamming distance between the codes, that is, the total number of inversions of the logic level for each bit digit, is “8”.

As a result, a current corresponding to the number of inversions of the logic level flows suddenly in each of the data register latch and the DA conversion part, and this causes noise. Therefore, there is a risk that the noise may be superimposed on the output voltage and cause the image quality to deteriorate.

The disclosure provides a digital-to-analog conversion device capable of generating a high-quality output voltage with noise superimposition suppressed, and a display driver and a display device including the digital-to-analog conversion device.

### SUMMARY

A digital-to-analog conversion device according to the disclosure includes: a Gray code conversion circuit receiving a series of digital data pieces including binary codes, and generating Gray code data pieces obtained by respectively converting the digital data pieces into Gray codes; a decoder receiving the Gray code data pieces and a plurality of reference voltages having different voltage values, selecting two reference voltages including an overlap from the plurality of reference voltages based on the Gray code data pieces, and outputting the two reference voltages as a first selection voltage and a second selection voltage, respectively; and an amplifier circuit including a first input terminal and a second input terminal that respectively receive the first selection voltage and the second selection voltage, and generating an output voltage by amplifying a voltage that is obtained by interpolating the first selection voltage and the second selection voltage by a weighting ratio assigned to the first input terminal and the second input terminal.

A display driver according to the disclosure includes first to n^{th} digital-to-analog conversion circuits that receive a series of pixel data pieces, each of which represents a luminance level of each pixel based on a video signal in a binary code, convert the pixel data pieces into first to n^{th} output voltages having voltage values corresponding to the luminance levels for each of n (n is an integer greater than or equal to 2) pixel data pieces included in the series of pixel data pieces, and supply the first to n^{th} output voltages to first to n^{th} data lines of a display panel. The display driver includes: a Gray code conversion circuit generating Gray code data pieces by respectively converting the pixel data pieces included in the series of pixel data pieces into Gray codes, in which each of the first to n^{th} digital-to-analog conversion circuits includes: a decoder receiving the Gray code data pieces and a plurality of reference voltages having different voltage values, selecting two reference voltages including an overlap from the plurality of reference voltages based on the Gray code data pieces, and outputting the two reference voltages as a first selection voltage and a second selection voltage, respectively; and an amplifier circuit including a first input terminal and a second input terminal that respectively receive the first selection voltage and the second selection voltage, and generating, as the output voltage, a voltage obtained by interpolating the first selection voltage and the second selection voltage by a weighting ratio assigned to the first input terminal and the second input terminal.

A display device according to the disclosure includes: a display panel on which first to n^{th} (n is an integer greater than or equal to 2) data lines are arranged, each of which includes a plurality of display cells formed thereon; a display driver including first to n^{th} digital-to-analog conversion circuits that receive a series of pixel data pieces, each of which represents a luminance level of each pixel based on a video signal in a binary code, convert the pixel data pieces into first to n^{th} output voltages having voltage values corresponding to the luminance levels for each of n pixel data pieces included in the series of pixel data pieces, and supply the first to n^{th} output voltages to the first to n^{th} data lines of the display panel; and a Gray code conversion circuit generating Gray code data pieces by respectively converting the pixel data pieces included in the series of pixel data pieces into Gray codes, in which each of the first to n^{th} digital-to-analog conversion circuits includes: a decoder receiving the Gray code data pieces and a plurality of reference voltages having different voltage values, selecting two reference voltages including an overlap from the plurality of reference voltages based on the Gray code data pieces, and outputting the two reference voltages as a first selection voltage and a second selection voltage, respectively; and an amplifier circuit including a first input terminal and a second input terminal that respectively receive the first selection voltage and the second selection voltage, and generating, as the output voltage, a voltage obtained by interpolating the first selection voltage and the second selection voltage by a weighting ratio assigned to the first input terminal and the second input terminal.

### BRIEF DESCRIPTION OF THE DRAWINGS

FIG. 1 is a block diagram showing the configuration of the display device 200.

FIG. 2 is a block diagram showing the internal configuration of the data driver 13.

FIG. 3 is a diagram showing an example of binary code/Gray code conversion.

FIG. 4 is a block diagram showing an example of the configuration of the DA conversion circuit DA1.

FIG. 5 is a circuit diagram showing an example of the internal configuration of the first decoder DE1 and the second decoder DE2.

FIG. 6A is a diagram showing the operation of the first decoder DE1.

FIG. 6B is a diagram showing the operation of the selection circuit EXSEL.

FIG. 6C is a diagram showing the operation of the selection circuit SEL.

FIG. 7 is a diagram showing the operation of the first decoder DE1 and the second decoder DE2.

FIG. 8 is a circuit diagram showing another example of the internal configuration of the second decoder DE2.

FIG. 9 is a diagram showing the internal operation of the second decoder DE2 shown in FIG. 8.

FIG. 10A is a circuit diagram showing a part of another example of the internal configuration of the second decoder DE2.

FIG. 10B is a circuit diagram showing a part of another example of the internal configuration of the second decoder DE2.

FIG. 11A is a diagram showing a part of the internal operation of the second decoder DE2 shown in FIG. 10A and FIG. 10B.

FIG. 11B is a diagram showing another part of the internal operation of the second decoder DE2 shown in FIG. 10A and FIG. 10B.

FIG. 12 is a block diagram showing a modified example of the DA conversion circuit.

FIG. 13 is a block diagram showing the configuration of the DA conversion device 300.

### DETAILED DESCRIPTION

In the disclosure, a series of digital data pieces represented by a binary code is received, each digital data piece is converted into a Gray code, and each of the Gray code data pieces converted into the Gray code is digital-to-analog converted to generate an output voltage having an analog voltage value.

Thus, it is possible to generate a high-quality output voltage with a reduced amount of noise generated during transition between adjacent gradations in the digital data piece.

### Example 1

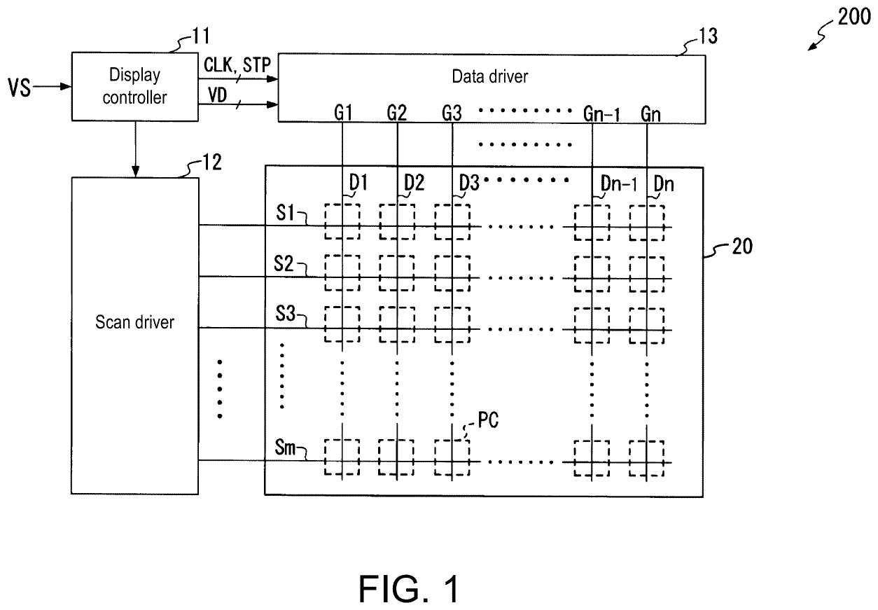

FIG. 1 is a block diagram showing the schematic configuration of a display device 200 including a display driver according to the disclosure.

As shown in FIG. 1, the display device 200 includes a display panel 20, a display controller 11, a scan driver 12, and a data driver 13 serving as a display driver.

The display panel 20 is composed of, for example, a liquid crystal or organic EL (electroluminescence) panel, and includes horizontal scan lines S1 to Sm (m is an integer greater than or equal to 2) extending in the horizontal direction of a two-dimensional screen, and data lines D1 to Dn (n is an integer greater than or equal to 2) extending in the vertical direction of the two-dimensional screen. At each intersection of the horizontal scan lines and the data lines, a display cell PC serving as a pixel is formed.

The display controller 11 receives a video signal VS, and supplies to the scan driver 12 a scan timing signal indicating the timing for sequentially selecting the horizontal scan lines S1 to Sm according to the video signal VS.

Further, the display controller 11 generates various control signals including a start pulse signal STP and a clock signal CLK, and a video data signal VD, based on the video signal VS. The start pulse signal STP is a single pulse signal that is generated according to a horizontal scan synchronization signal included in the video signal VS. In addition, the video data signal VD is a signal including a series of pixel data pieces that represent, in binary code, the luminance level of each display cell PC serving as a pixel. The display controller 11 supplies these video data signal VD and control signals to the data driver 13.

The scan driver 12 sequentially applies horizontal scan pulses to the horizontal scan lines S1 to Sm of the display panel 20 according to the scan timing signal supplied from the display controller 11.

According to the various control signals (including STP and CLK) supplied from the display controller 11, the data driver 13 converts each of n pixel data pieces in the series of pixel data pieces included in the video data signal VD into an analog voltage having a magnitude corresponding to the luminance level indicated by that pixel data piece. Then, the data driver 13 supplies the n voltages, which are obtained by respectively converting the n pixel data pieces into analog voltages, to the data lines D1 to Dn of the display panel 20 as output voltages G1 to Gn.

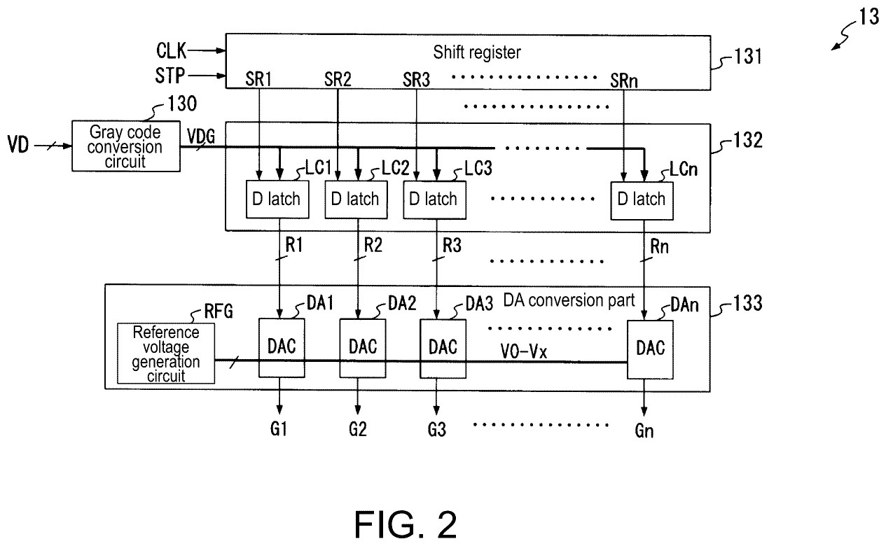

FIG. 2 is a block diagram showing the internal configuration of the data driver 13.

As shown in FIG. 2, the data driver 13 includes a Gray code conversion circuit 130, a shift register 131, a data latch part 132, and a DA (digital-to-analog) conversion part 133.

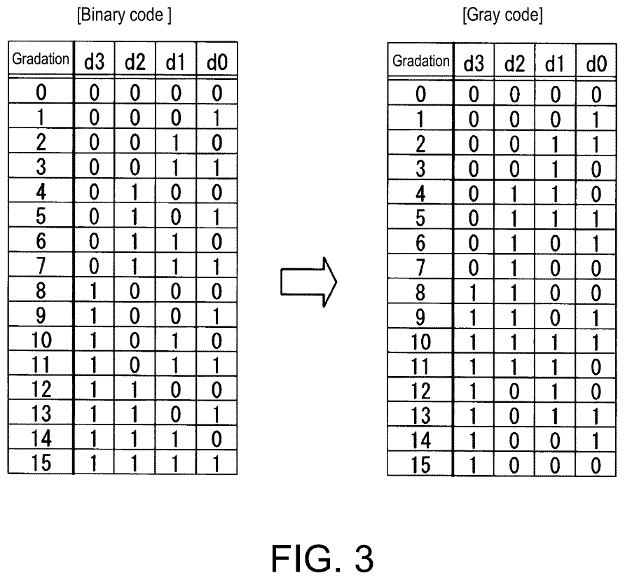

The Gray code conversion circuit 130 receives the video data signal VD, and converts each of the pixel data pieces included in the video data signal VD into a Gray code. For example, as shown in FIG. 3, the Gray code conversion circuit 130 converts each of the pixel data pieces, each of which is composed of a binary code capable of expressing 16 gradation s with, for example, 4 bits (d3 to d0), into a 4-bit (d3 to d0) Gray code. Then, the Gray code conversion circuit 130 supplies a series VDG of Gray code data pieces obtained by individually converting each pixel data piece into a Gray code to the data latch part 132.

When the shift register 131 receives the start pulse signal STP which is a single pulse signal, the shift register 131 shifts this sequentially at a timing synchronized with the clock signal CLK to generate n systems of latch timing signals SR1 to SRn, each of which produces a single pulse at a different timing. The shift register 131 supplies the latch timing signals SR1 to SRn to the data latch part 132.

The data latch part 132 includes data latches LC1 to LCn which receive the latch timing signals SR1 to SRn individually. The data latch LC1 latches one Gray code data piece included in the series VDG of Gray code data pieces at the timing of a single pulse included in the latch timing signal SR1. The data latch LC2 latches one Gray code data piece included in the series VDG of Gray code data pieces at the timing of a single pulse included in the latch timing signal SR2. Similarly, each of the data latches LC3 to LCn latches one Gray code data piece included in the series VDG of Gray code data pieces at the timing of a single pulse included in the latch timing signal SRj (j is an integer of 3 to n) that the data latch receives.

Then, the data latches LC1 to LCn simultaneously supply the n pieces of Gray code data (hereinafter also referred to as GR data) that the data latches LC1 to LCn have latched as described above to the DA conversion part 133 as GR data R1 to Rn.

The DA conversion part 133 includes a reference voltage generation circuit RFG that generates a plurality of reference voltages V0 to Vx (x is an integer greater than or equal to 1) having different voltage values, and DA conversion circuits DA1 to DAn provided corresponding to the GR data R1 to Rn, respectively.

The DA conversion circuits DA1 to DAn individually receive the corresponding GR data R1 to Rn, convert the GR data R1 to Rn into output voltages G1 to Gn having analog voltage values by using the above-mentioned reference voltages V0 to Vx, and output the output voltages G1 to Gn. The DA conversion circuits DA1 to DAn have the same internal configuration.

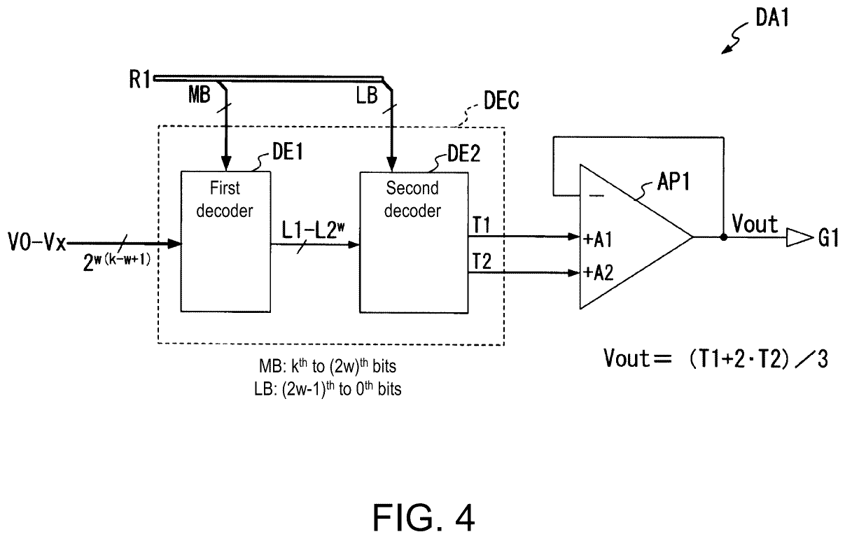

FIG. 4 is a block diagram showing the internal configuration of the DA conversion circuit DA1 selected from the DA conversion circuits DA1 to DAn.

As shown in FIG. 4, the DA conversion circuit DA1 includes a decoder DEC and an amplifier circuit AP1.

The decoder DEC receives the reference voltages V0 to Vx supplied from the reference voltage generation circuit RFG, and the GR data R1 composed of a Gray code of a total of (k+1) bits, including the k^{th} (k is an integer greater than or equal to 2) bit (most significant bit) to the 0^{th} bit (least significant bit).

The decoder DEC includes a first decoder DE1 and a second decoder DE2.

The first decoder DE1 receives an upper bit group MB including the most significant bit in the GR data R1, and selects 2^{w} (w is an integer greater than or equal to 1) reference voltages having adjacent values from the reference voltages V0 to Vx based on the upper bit group MB.

The total number of reference voltages V0 to Vx is 2^{(k-w+1)}, and the upper bit group MB is the k^{th} bit (most significant bit) to the (2·w)^{th} bit in the GR data R1. Here, “w” is a value that satisfies the relationship of k≥(2w−1)>0.

The first decoder DE1 supplies the selected 2^{w} reference voltages to the second decoder DE2 as selection voltages L1 to L2^{w}.

The second decoder DE2 receives a lower bit group LB including the least significant bit in the GR data R1, as well as the selection voltages L1 to L2^{w}. The lower bit group LB is the (2·w−1)^{th} bit to the 0^{th} bit (least significant bit) in the GR data R1.

The second decoder DE2 selects two of the above-mentioned selection voltages L1 to L2^{w} that include an overlap based on the lower bit group LB, and supplies the same to the amplifier circuit AP1 as a first selection voltage T1 and a second selection voltage T2. In the DA conversion circuit DA1 shown in FIG. 2, the selection voltages T1 and T2 output from the second decoder DE2 are supplied to the amplifier circuit AP1 as the above-mentioned selection voltage pair J1.

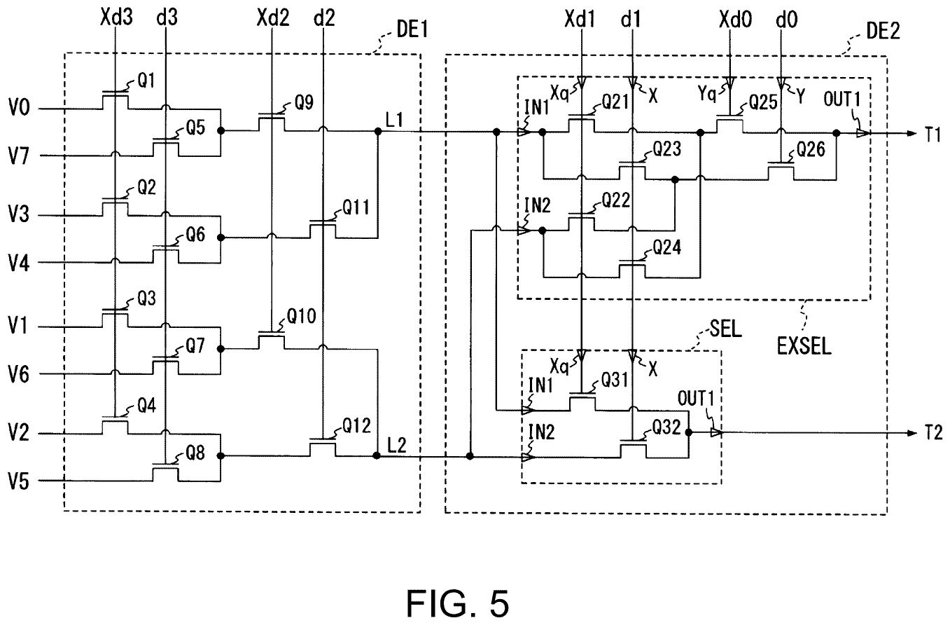

FIG. 5 is a circuit diagram showing an example of the internal configuration of the first decoder DE1 and the second decoder DE2. FIG. 5 shows circuits that are applied as the first decoder DE1 and the second decoder DE2 in the case where “k” is 3 and “w” is 1.

In other words, the GR data R1 is a 4-bit Gray code composed of the third bit d3 to the 0^{th} bit d0 shown in FIG. 3, the upper bit group MB is the third and second bits (d3, d2) of the four bits, and the lower bit group LB is the first and 0^{th} bits (d1, d). Furthermore, the reference voltage group includes reference voltages V0 to V7 whose respective voltage values have the following magnitude relationship.

V7>V6>V5>V4>V3>V2>V1>V0

Furthermore, in FIG. 5, Xd3 is the inversion of the logic level of the third bit d3 in the GR data R1, Xd2 is the inversion of the logic level of the second bit d2, Xd1 is the inversion of the logic level of the first bit d1, and Xd0 is the inversion of the logic level of the 0^{th} bit d0.

As shown in FIG. 5, the first decoder DE1 includes N-channel type transistors Q1 to Q12 as switching elements.

The transistors Q1 and Q5 supply the reference voltage V0 to the transistor Q9 in the case where the third bit d3 is at logic level 1, and supply the reference voltage V7 to the transistor Q9 in the case where the third bit d3 is at logic level 0.

The transistors Q2 and Q6 supply the reference voltage V4 to the transistor Q11 in the case where the third bit d3 is at logic level 1, and supply the reference voltage V3 to the transistor Q11 in the case where the third bit d3 is at logic level 0.

The transistors Q3 and Q7 supply the reference voltage V6 to the transistor Q10 in the case where the third bit d3 is at logic level 1, and supply the reference voltage V1 to the transistor Q10 in the case where the third bit d3 is at logic level 0.

The transistors Q4 and Q8 supply the reference voltage V5 to the transistor Q12 in the case where the third bit d3 is at logic level 1, and supply the reference voltage V2 to the transistor Q12 in the case where the third bit d3 is at logic level 0.

In the case where the second bit d2 is at logic level 1, the transistors Q9 and Q11 supply the reference voltage V0 or V7 supplied via the transistor Q1 or Q5 to the second decoder DE2 as the selection voltage L1. On the other hand, in the case where the second bit d2 is at logic level 0, the transistors Q9 and Q11 supply the reference voltage V3 or V4 supplied via the transistor Q2 or Q6 to the second decoder DE2 as the selection voltage L1.

In the case where the second bit d2 is at logic level 1, the transistors Q10 and Q12 supply the reference voltage V2 or V5 supplied via the transistor Q4 or Q8 to the second decoder DE2 as the selection voltage L2. On the other hand, in the case where the second bit d2 is at logic level 0, the transistors Q10 and Q12 supply the reference voltage V2 or V5 supplied via the transistor Q4 or Q8 to the second decoder DE2 as the selection voltage L2.

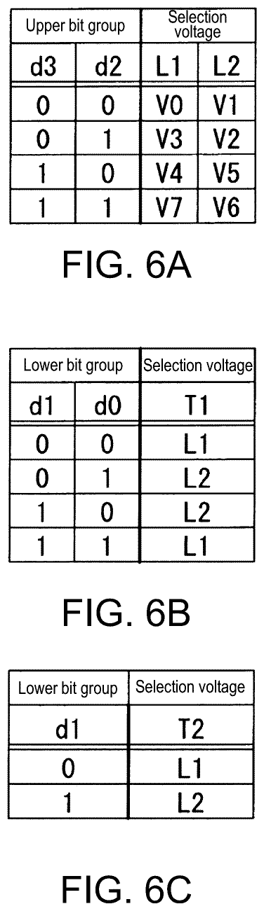

FIG. 6A is a diagram showing the contents of the selection voltages L1 and L2 output by the first decoder DE1 in accordance with the third bit d3 and the second bit d2, which are the upper bit group in the GR data R1, by the configuration shown in FIG. 5.

As shown in FIG. 5, the second decoder DE2 includes a selection circuit EXSEL composed of N-channel type transistors Q21 to Q26, and a selection circuit SEL composed of N-channel type transistors Q31 and Q32.

In the selection circuit EXSEL, in the case where the first bit d1 is at logic level 1, the transistors Q21 and Q24 supply the selection voltage L2 supplied from the first decoder DE1 to the transistor Q25. On the other hand, in the case where the first bit d1 is at logic level 0, the transistors Q21 and Q24 supply the selection voltage L1 supplied from the first decoder DE1 to the transistor Q25.

In the case where the first bit d1 is at logic level 1, the transistors Q22 and Q23 supply the selection voltage L1 supplied from the first decoder DE1 to the transistor Q26. On the other hand, in the case where the first bit d1 is at logic level 0, the transistors Q22 and Q23 supply the selection voltage L2 supplied from the first decoder DE1 to the transistor Q26.

In the case where the 0^{th} bit d0 is at logic level 1, the transistors Q25 and Q26 output the selection voltage L1 or L2 supplied via the transistor Q22 or Q23 as the selection voltage T1. On the other hand, in the case where the 0^{th} bit d0 is at logic level 0, the transistors Q25 and Q26 output the selection voltage L1 or L2 supplied via the transistor Q21 or Q24 as the selection voltage T1.

FIG. 6B is a diagram showing the contents of the selection voltage T1 output by the selection circuit EXSEL of the second decoder DE2 in accordance with the first bit d1 and the 0^{th} bit d0, which are the lower bit group in the GR data R1, by the configuration shown in FIG. 5.

In the selection circuit SEL, in the case where the first bit d1 is at logic level 1, the transistors Q31 and Q32 output the selection voltage L2 supplied from the first decoder DE1 as the selection voltage T2. On the other hand, in the case where the first bit d1 is at logic level 0, the selection voltage L1 supplied from the first decoder DE1 is output as the selection voltage T2.

FIG. 6C is a diagram showing the contents of the selection voltage T2 output by the selection circuit SEL of the second decoder DE2 in accordance with the first bit d1, which is the lower bit group in the GR data R1, by the configuration shown in FIG. 5.

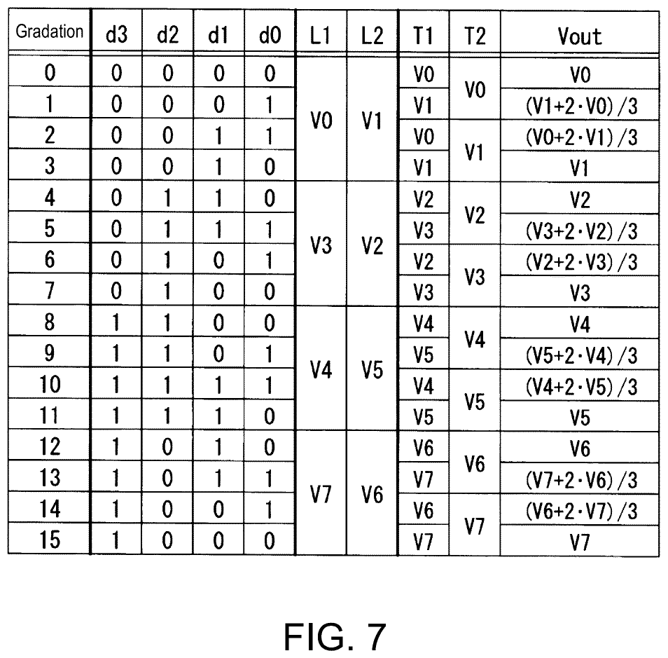

As a result, as shown in FIG. 7, the first decoder DE1 outputs the selection voltages L1 and L2 indicating one of the reference voltages V0 to V7 in accordance with the contents of the third bit d3 to the 0^{th} bit d0 in the GR data R1. Furthermore, the second decoder DE2 selects two reference voltages including an overlap from the reference voltages V0 to V7, and supplies the same to the amplifier circuit AP1 as the selection voltages T1 and T2, respectively.

The amplifier circuit AP1 is an operational amplifier having an interpolation function, the output terminal of which is connected to the inverting input terminal of which, and the operational amplifier includes two non-inverting input terminals +A1 and +A2 that receive the selection voltages T1 and T2, respectively.

The amplifier circuit AP1 performs interpolation between the selection voltage T1 received at the non-inverting input terminal +A1 and the selection voltage T2 received at the non-inverting input terminal +A2 by the weighting ratio that is preset for each of the non-inverting input terminals +A1 and +A2, and generates the amplified voltage obtained as the result as an output voltage Vout.

For example, in the case where the weighting ratio assigned to the non-inverting input terminal +A1 and the non-inverting input terminal +A2 is:

$$+ A 1 : + A 2 = 1 : 2 ,$$

the amplifier circuit AP1 outputs the output voltage Vout indicated by:

$$Vout = ( T 1 + 2 \cdot T 2 ) / 3.$$

For example, the DA conversion circuit DA1 outputs the output voltage Vout output from its own amplifier circuit AP1 as an output voltage G1.

Therefore, according to the configuration of each of the DA conversion circuits DA1 to DAn shown in FIG. 4, it is possible to obtain an output voltage Vout for 16 gradations, each having a different voltage value, as shown in FIG. 7, by using eight systems of reference voltages V0 to V7.

Each of the DA conversion circuits DA1 to DAn outputs the output voltage Vout output from its own amplifier circuit AP1 as the output voltages G1 to Gn.

Furthermore, in the data driver 13, each of the GR data pieces, which is obtained by converting each pixel data piece representing the luminance level of each pixel based on the video signal VS in, for example, 4 bits from binary code into Gray code, is taken in by the data latch part 132. At this time, the data latch part 132 supplies the n GR data pieces taken therein to the DA conversion part 133 as GR data R1 to Rn. The DA conversion part 133 converts each piece of the GR data R1 to Rn into an analog voltage value corresponding to the luminance level represented by the original binary code.

In this case, in Gray code, the Hamming distance between adjacent codes is always “1”. For example, as shown in FIG. 3, the total number of inversions of the logic level between adjacent codes (d3 to d0) at the same bit digit is “1”.

Therefore, in the data latch part 132 and the decoder DEC of the DA conversion part 133, the frequency of logic level inversion occurring at each bit is significantly reduced compared to the case where the n pixel data pieces are received directly in the form of binary code, and accordingly, the current flows within the data latch part 132 and the DA conversion part 133 decreases. This suppresses noise caused by a sudden increase in the current flowing within the data latch part 132 and the DA conversion part 133 due to transition of the pixel data pieces. Thus, the data driver 13 is capable of outputting high-quality output voltages G1 to Gn without noise being superimposed thereon.

### Example 2

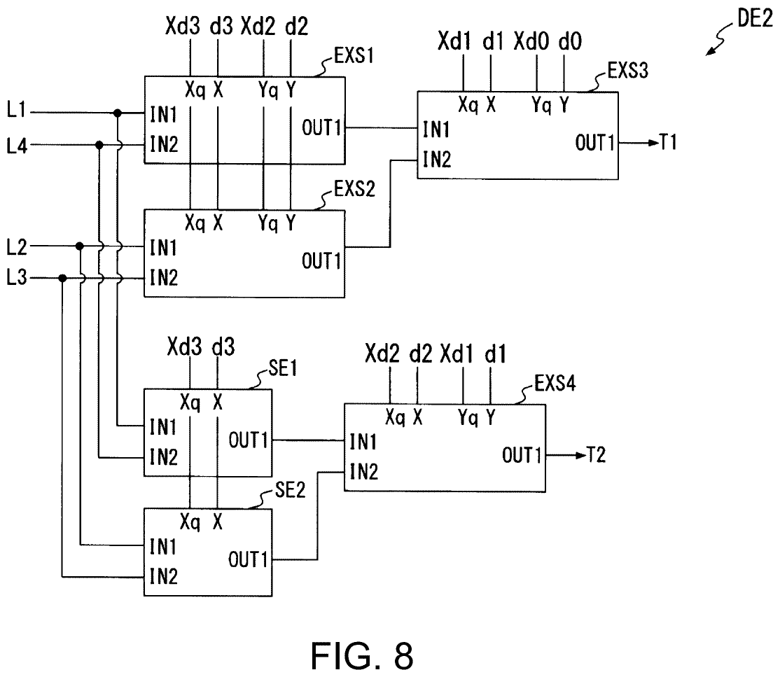

FIG. 8 is a circuit diagram showing an example of the internal configuration of the second decoder DE2 of each of the DA conversion circuits DA1 to DAn in the case where “w” is 2, that is, in the case where the number of bits of the lower bit group LB is 4. In this case, the second decoder DE2 receives four selection voltages L1 to L4, as well as four bits composed of the third bit d3 to the 0^{th} bit d0 as the lower bit group LB.

The second decoder DE2 shown in FIG. 8 includes selection circuits EXS1 to EXS4 each having the same internal configuration as the selection circuit EXSEL shown in FIG. 5, and selection circuits SE1 and SE2 having the same internal configuration as the selection circuit SEL shown in FIG. 5.

In FIG. 8, the selection circuit EXS1 supplies the selection voltage L1 or L4 to the selection circuit EXS3 according to the third bit d3 and the second bit d2. The selection circuit EXS2 supplies the selection voltage L2 or L3 to the selection circuit EXS3 according to the third bit d3 and the second bit d2.

The selection circuit EXS3 outputs, as the selection voltage T1, the selection voltage L1 or L4 supplied from the selection circuit EXS1, or the selection voltage L2 or L3 supplied from the selection circuit EXS2, according to the first bit d1 and the 0^{th} bit d0.

The selection circuit SE1 supplies the selection voltage L1 or L4 to the selection circuit EXS4 according to the third bit d3. The selection circuit SE2 supplies the selection voltage L2 or L3 to the selection circuit EXS4 according to the third bit d3.

The selection circuit EXS4 outputs, as the selection voltage T2, the selection voltage L1 or L4 supplied from the selection circuit SE1, or the selection voltage L2 or L3 supplied from the selection circuit SE2, according to the second bit d2 and the first bit d1.

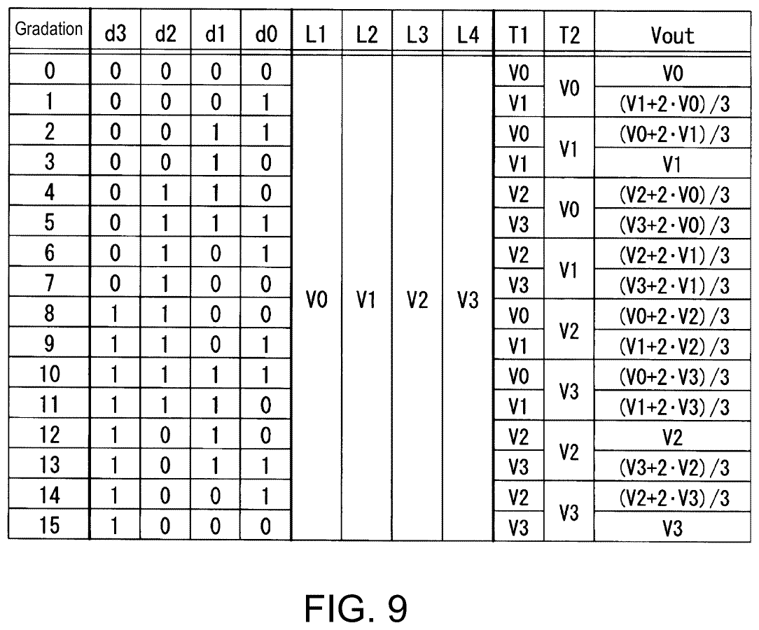

FIG. 9 is a diagram showing the internal operation of the second decoder DE2 shown in FIG. 8.

According to the configuration shown in FIG. 8, the second decoder DE2 selects two of the reference voltages V0 to V3 that include an overlap according to the four bits from the third bit d3 to the 0^{th} bit d0, as shown in FIG. 9, and supplies the same to the amplifier circuit AP1 as the selection voltages T1 and T2, respectively. At this time, the amplifier circuit AP1 generates the output voltage Vout by amplifying a voltage obtained by interpolating the selection voltage T1 and the selection voltage T2.

Therefore, according to the second decoder DE2 shown in FIG. 8, it is possible to obtain an output voltage Vout for 16 gradations, each having a different voltage value, as shown in FIG. 9, by using four systems of reference voltages V0 to V3.

### Example 3

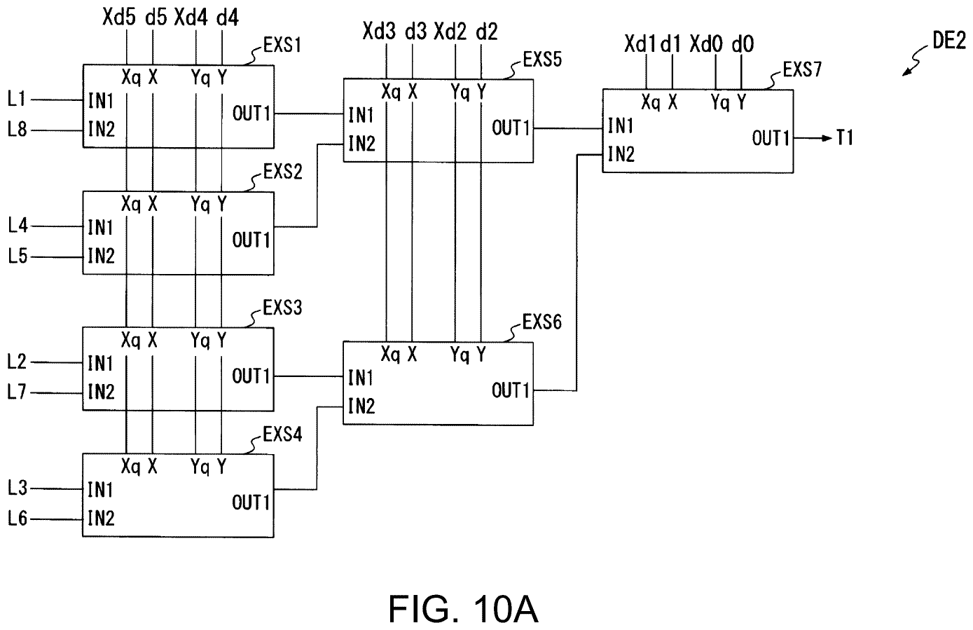

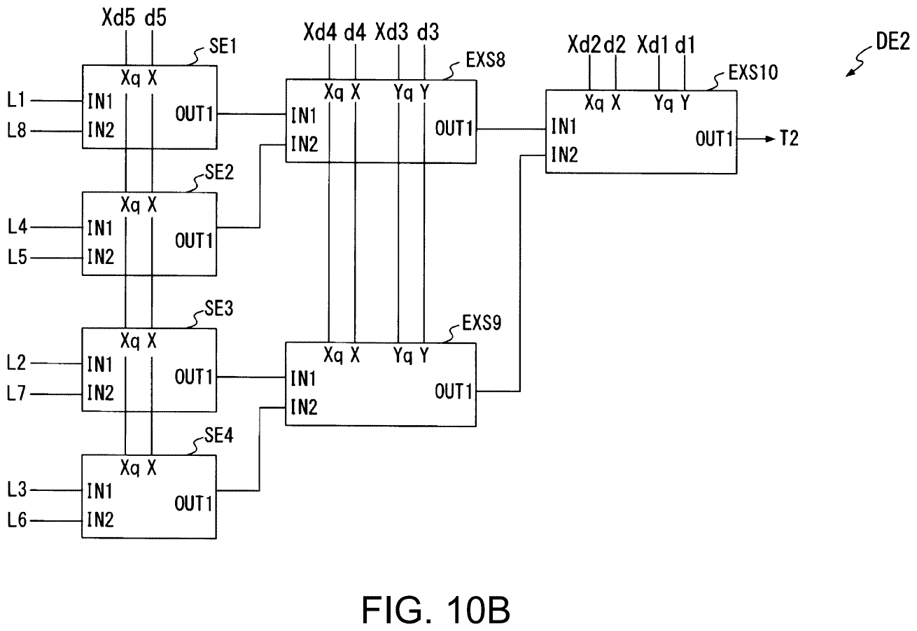

FIG. 10A and FIG. 10B are circuit diagrams showing an example of the internal configuration of the second decoder DE2 of each of the DA conversion circuits DA1 to DAn in the case where “w” is 3, that is, in the case where the number of bits of the lower bit group LB is 6. In this case, the second decoder DE2 receives the 6 bits composed of the fifth bit d5 to the 0^{th} bit d0 as the lower bit group LB, as well as 8 selection voltages L1 to L8.

The second decoder DE2 shown in FIG. 10A and FIG. 10B includes selection circuits EXS1 to EXS10 each having the same internal configuration as the selection circuit EXSEL shown in FIG. 5, and selection circuits SE1 to SE4 having the same internal configuration as the selection circuit SEL shown in FIG. 5.

In FIG. 10A, the selection circuit EXS1 supplies the selection voltage L1 or L8 to the selection circuit EXS5 according to the fifth bit d5 and the fourth bit d4. The selection circuit EXS2 supplies the selection voltage L4 or L5 to the selection circuit EXS5 according to the fifth bit d5 and the fourth bit d4. The selection circuit EXS3 supplies the selection voltage L2 or L7 to the selection circuit EXS6 according to the fifth bit d5 and the fourth bit d4. The selection circuit EXS4 supplies the selection voltage L3 or L6 to the selection circuit EXS6 according to the fifth bit d5 and the fourth bit d4.

The selection circuit EXS5 supplies the selection voltage L1 or L8 supplied from the selection circuit EXS1, or the selection voltage L4 or L5 supplied from the selection circuit EXS2, to the selection circuit EXS7 according to the third bit d3 and the second bit d2.

The selection circuit EXS6 supplies the selection voltage L2 or L7 supplied from the selection circuit EXS3, or the selection voltage L3 or L6 supplied from the selection circuit EXS4, to the selection circuit EXS7 according to the third bit d3 and the second bit d2.

The selection circuit EXS7 outputs, as the selection voltage T1, the selection voltage L1, L8, L4, or L5 supplied from the selection circuit EXS5, or the selection voltage L2, L7, L3, or L6 supplied from the selection circuit EXS6, according to the first bit d1 and the 0^{th} bit d0.

In FIG. 10B, the selection circuit SE1 supplies the selection voltage L1 or L8 to the selection circuit EXS8 according to the fifth bit d5. The selection circuit SE2 supplies the selection voltage L4 or L5 to the selection circuit EXS8 according to the fifth bit d5. The selection circuit SE3 supplies the selection voltage L2 or L7 to the selection circuit EXS9 according to the fifth bit d5. The selection circuit SE4 supplies the selection voltage L3 or L6 to the selection circuit EXS9 according to the fifth bit d5.

The selection circuit EXS8 supplies the selection voltage L1 or L8 supplied from the selection circuit SE1, or the selection voltage L4 or L5 supplied from the selection circuit SE2, to the selection circuit EXS10 according to the fourth bit d4 and the third bit d3.

The selection circuit EXS9 supplies the selection voltage L2 or L7 supplied from the selection circuit SE3, or the selection voltage L3 or L6 supplied from the selection circuit SE4, to the selection circuit EXS10 according to the fourth bit d4 and the third bit d3.

The selection circuit EXS10 outputs, as the selection voltage T2, the selection voltage L1, L8, L4, or L5 supplied from the selection circuit EXS8, or the selection voltage L2, L7, L3, or L6 supplied from the selection circuit EXS9, according to the second bit d2 and the first bit d1.

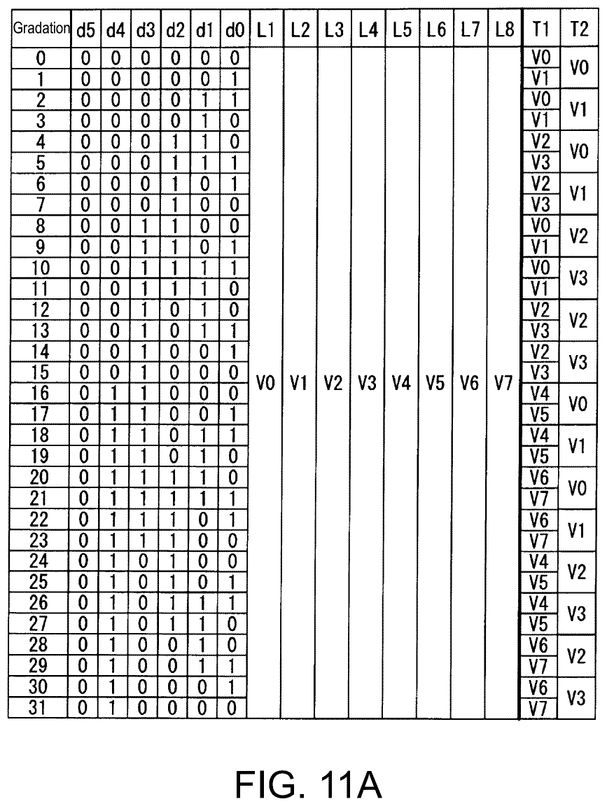

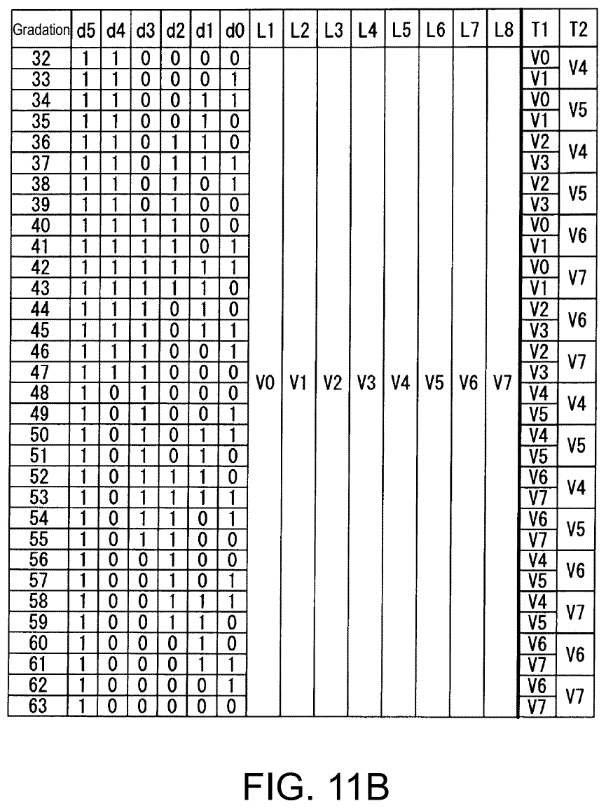

FIG. 11A and FIG. 11B are diagrams showing the internal operation of the second decoder DE2 shown in FIG. 10A and FIG. 10B.

According to the configuration shown in FIG. 10A and FIG. 10B, the second decoder DE2 selects two of the reference voltages V0 to V7 that include an overlap according to the six bits from the fifth bit d5 to the 0^{th} bit d0, as shown in FIG. 11A and FIG. 11B, and supplies the same to the non-inverting input terminals +A1 and +A2 as the selection voltages T1 and T2, respectively. At this time, the amplifier circuit AP1 generates the output voltage Vout by amplifying a voltage obtained by interpolating the selection voltage T1 and the selection voltage T2, by a weighting ratio assigned to the non-inverting input terminals +A1 and +A2.

Therefore, according to the second decoder DE2 shown in FIG. 10A and FIG. 10B, it is possible to obtain an output voltage Vout for 64 gradations, each having a different voltage value, as shown in FIG. 11A and FIG. 11B, by using eight systems of reference voltages V0 to V7.

### Example 4

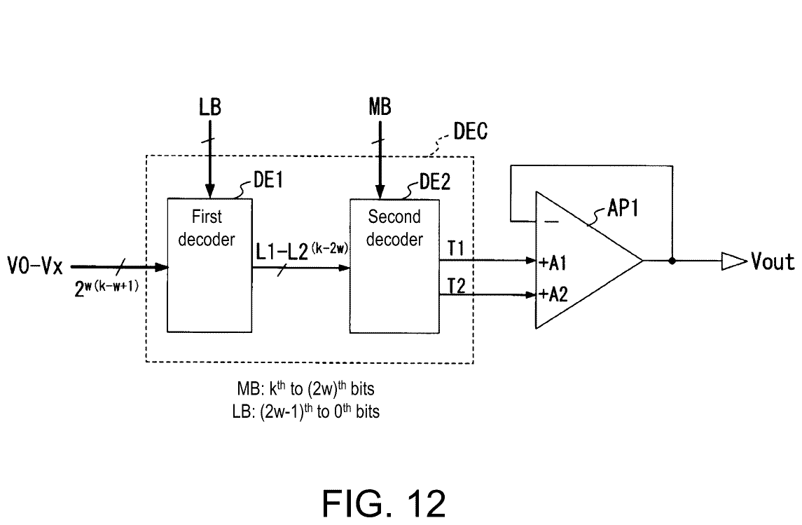

FIG. 12 is a block diagram of a DA conversion circuit that shows a modified example of the decoder DEC shown in FIG. 4.

The decoder DEC shown in FIG. 12 includes a first decoder DE1 and a second decoder DE2, similar to the decoder DEC shown in FIG. 4. However, in the decoder DEC shown in FIG. 12, the first decoder DE1 selects 2^{(k-2w)} reference voltages having different voltage values from the reference voltages V0 to Vx in accordance with the lower bit group LB composed of the (2w−1)^{th} to 0^{th} bits in the GR data piece as a Gray code data piece, and supplies the same to the second decoder DE2 as selection voltages L1 to L2^{(k-2w)}, respectively. The second decoder DE2 selects two selection voltages including an overlap from the selection voltages L1 to L2^{(k-2w)} in accordance with the upper bit group MB composed of the k^{th} to (2w)^{th} bits in the GR data piece, and supplies the same as the selection voltages T1 and T2, respectively, to the non-inverting input terminals +A1 and +A2 of the amplifier circuit AP1.

In Examples 1 to 4 described above, in order to convert each of the n pixel data pieces into an analog voltage value, n DA conversion circuits (DA1 to DAn) each having the configuration shown in FIG. 4 or FIG. 12, and the Gray code conversion circuit 130 are provided in the data driver 13.

However, the use thereof is not limited to DA conversion for pixel data pieces, and a configuration including a DA conversion circuit and a Gray code conversion circuit as shown in FIG. 4 or FIG. 12 may be adopted as a DA conversion device that simply converts digital data into an analog output voltage.

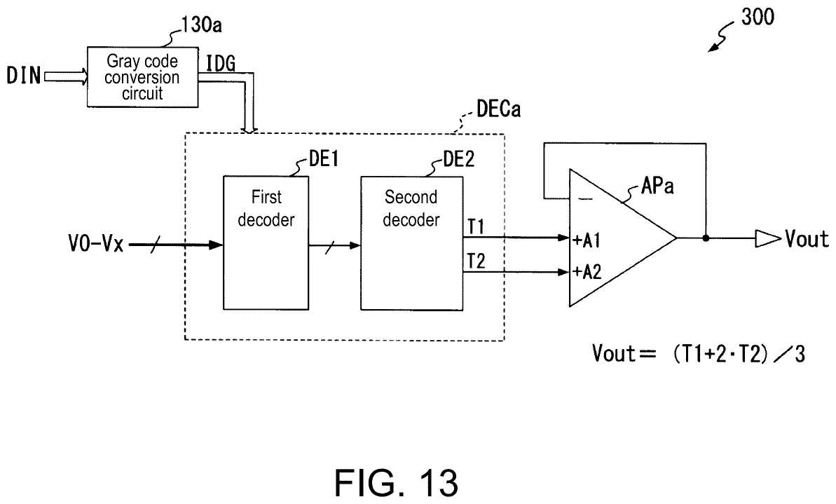

FIG. 13 is a block diagram showing the configuration of a DA (digital-to-analog) conversion device 300 according to the disclosure, which has been made in view of such points.

As shown in FIG. 13, the DA conversion device 300 includes a Gray code conversion circuit 130a that is the same as the Gray code conversion circuit 130 shown in FIG. 2, and a decoder DECa and an amplifier circuit APa that respectively have the same configurations as the decoder DEC and the amplifier circuit AP1 shown in FIG. 4 or FIG. 12.

The Gray code conversion circuit 130a receives a series DIN of digital data pieces composed of binary codes, and supplies a series IDG of Gray code data pieces obtained by converting each of the digital data pieces into a Gray code to the decoder DECa. The decoder DECa includes the first decoder DE1 and the second decoder DE2 shown in FIG. 4 or FIG. 12, and receives reference voltages V0 to Vx having different voltage values and the series IDG of Gray code data pieces.

The decoder DECa selects two reference voltages including an overlap from the reference voltages V0 to Vx based on each Gray code data piece in the series IDG of Gray code data pieces by the operations of the first decoder DE1 and the second decoder DE2 described above. Then, the decoder DECa supplies the two selected reference voltages as selection voltages T1 and T2 to the non-inverting input terminals +A1 and +A2 of the amplifier circuit APa. The amplifier circuit APa generates an output voltage Vout by amplifying a voltage obtained by interpolating the selection voltage T1 and the selection voltage T2, by a weighting ratio assigned to the non-inverting input terminals +A1 and +A2.

In short, such a single DA conversion device 300 or the DA conversion device included in the data driver 13 of the display device 200 may include the following Gray code conversion circuit, decoder, and amplifier circuit.

The Gray code conversion circuit (130, 130a) receives digital data pieces composed of binary codes to be converted, and generates Gray code data pieces (VDG, IDG) by converting the digital data pieces into Gray codes.

The decoder (DEC, DECa) receives a plurality of reference voltages (V0 to Vx) having different voltage values and the Gray code data pieces, selects two reference voltages including an overlap from the plurality of reference voltages based on the Gray code data pieces, and outputs the same as first and second selection voltages, respectively.

The amplifier circuit (AP1, APa) has first and second input terminals (+A1, +A2), receives the above-mentioned first and second selection voltages at the first and second input terminals, and generates an output voltage by amplifying a voltage obtained by interpolating the first selection voltage and the second selection voltage, by a weighting ratio assigned to the first and second input terminals.

In the example shown in FIG. 13, the digital data pieces composed of binary codes to be converted are converted into Gray codes by the Gray code conversion circuit 130a to obtain Gray code data pieces, and the Gray code data pieces are converted into the analog output voltage Vout by the DA conversion circuit (DECa, APa). With such a configuration, the frequency of bit inversions occurring in the Gray code data piece in response to the transition of the digital data pieces is less than the number of bit inversions in the digital data pieces. Therefore, the amount of change in the current flowing within the decoder DECa in response to the transition of the Gray code data pieces is also reduced, and noise caused by the change in the current is suppressed.

Although the DA conversion circuit (DECa, APa) shown in FIG. 13 obtains an analog output voltage by interpolating two voltages selected from a plurality of reference voltages (V0 to Vx) based on digital data pieces, the Gray code conversion circuit 130a may be added to a DA conversion circuit that employs a DA conversion system other than such a DA conversion circuit.

What is claimed is:

1. A digital-to-analog conversion device, comprising:
a Gray code conversion circuit receiving a series of digital data pieces including binary codes, and generating Gray code data pieces obtained by respectively converting the digital data pieces into Gray codes;
a decoder receiving the Gray code data pieces and a plurality of reference voltages having different voltage values, selecting two reference voltages including an overlap from the plurality of reference voltages based on the Gray code data pieces, and outputting the two reference voltages as a first selection voltage and a second selection voltage, respectively; and
an amplifier circuit comprising a first input terminal and a second input terminal that respectively receive the first selection voltage and the second selection voltage, and generating an output voltage by amplifying a voltage that is obtained by interpolating the first selection voltage and the second selection voltage by a weighting ratio assigned to the first input terminal and the second input terminal.

2. The digital-to-analog conversion device according to claim 1, wherein the decoder comprises:
a first decoder selecting 2^{w} (w is an integer greater than or equal to 1) reference voltages having adjacent voltage values from the plurality of reference voltages based on a first bit group in the Gray code data pieces, and outputting the 2^{w} reference voltages as first to 2^{wth} selection voltages, respectively; and
a second decoder selecting two reference voltages including the overlap from the first to 2^{wth} selection voltages based on a second bit group in the Gray code data pieces, and outputting the two reference voltages as the first selection voltage and the second selection voltage, respectively.

3. The digital-to-analog conversion device according to claim 2, wherein each of the Gray code data pieces comprises a total of (k+1) bits, with a most significant bit being a k^{th} (k is an integer greater than or equal to 2) bit and a least significant bit being a 0^{th} bit,
the first bit group is an upper bit group comprising the k^{th} bit to a (2·w)^{th} bit, and
the second bit group is a lower bit group comprising a (2·w−1)^{th} bit to the 0^{th} bit.

4. The digital-to-analog conversion device according to claim 2, wherein each of the Gray code data pieces comprises a total of (k+1) bits, with a most significant bit being a k^{th} (k is an integer greater than or equal to 2) bit and a least significant bit being a 0^{th} bit,
the first bit group is a lower bit group comprising a (2·w−1)^{th} bit to the 0^{th} bit, and
the second bit group is an upper bit group comprising the k^{th} bit to a (2·w)^{th} bit.

5. The digital-to-analog conversion device according to claim 1, wherein the amplifier circuit is an operational amplifier having an interpolation function, in which the first input terminal and the second input terminal are both non-inverting input terminals, and an output terminal thereof is connected to an inverting input terminal thereof.

6. The digital-to-analog conversion device according to claim 2, wherein the amplifier circuit is an operational amplifier having an interpolation function, in which the first input terminal and the second input terminal are both non-inverting input terminals, and an output terminal thereof is connected to an inverting input terminal thereof.

7. The digital-to-analog conversion device according to claim 3, wherein the amplifier circuit is an operational amplifier having an interpolation function, in which the first input terminal and the second input terminal are both non-inverting input terminals, and an output terminal thereof is connected to an inverting input terminal thereof.

8. The digital-to-analog conversion device according to claim 4, wherein the amplifier circuit is an operational amplifier having an interpolation function, in which the first input terminal and the second input terminal are both non-inverting input terminals, and an output terminal thereof is connected to an inverting input terminal thereof.

9. A display driver, comprising:
first to n^{th} digital-to-analog conversion circuits that receive a series of pixel data pieces, each of which represents a luminance level of each pixel based on a video signal in a binary code, convert the pixel data pieces into first to n^{th} output voltages having voltage values corresponding to the luminance levels for each of n (n is an integer greater than or equal to 2) pixel data pieces included in the series of pixel data pieces, and supply the first to n^{th} output voltages to first to n^{th} data lines of a display panel, and the display driver comprising:
a Gray code conversion circuit generating Gray code data pieces by respectively converting the pixel data pieces included in the series of pixel data pieces into Gray codes,
wherein each of the first to n^{th} digital-to-analog conversion circuits comprises:
a decoder receiving the Gray code data pieces and a plurality of reference voltages having different voltage values, selecting two reference voltages including an overlap from the plurality of reference voltages based on the Gray code data pieces, and outputting the two reference voltages as a first selection voltage and a second selection voltage, respectively; and
an amplifier circuit comprising a first input terminal and a second input terminal that respectively receive the first selection voltage and the second selection voltage, and generating, as the output voltage, a voltage obtained by interpolating the first selection voltage and the second selection voltage by a weighting ratio assigned to the first input terminal and the second input terminal.

10. A display device, comprising:
a display panel on which first to n^{th} (n is an integer greater than or equal to 2) data lines are arranged, each of which comprises a plurality of display cells formed thereon;
a display driver comprising first to n^{th} digital-to-analog conversion circuits that receive a series of pixel data pieces, each of which represents a luminance level of each pixel based on a video signal in a binary code, convert the pixel data pieces into first to n^{th} output voltages having voltage values corresponding to the luminance levels for each of n pixel data pieces included in the series of pixel data pieces, and supply the first to n^{th} output voltages to the first to n^{th} data lines of the display panel; and
a Gray code conversion circuit generating Gray code data pieces by respectively converting the pixel data pieces included in the series of pixel data pieces into Gray codes,
wherein each of the first to n^{th} digital-to-analog conversion circuits comprises:
a decoder receiving the Gray code data pieces and a plurality of reference voltages having different voltage values, selecting two reference voltages including an overlap from the plurality of reference voltages based on the Gray code data pieces, and outputting the two reference voltages as a first selection voltage and a second selection voltage, respectively; and
an amplifier circuit comprising a first input terminal and a second input terminal that respectively receive the first selection voltage and the second selection voltage, and generating, as the output voltage, a voltage obtained by interpolating the first selection voltage and the second selection voltage by a weighting ratio assigned to the first input terminal and the second input terminal.
